(19) United States
(12) Patent Application Publication
(10) Pub. No.: US 2002/0075045 A1
(43) Pub. Date: Jun. 20, 2002

(54) Frequency multiplier

(76) Inventor: Shuhei Kawauchi, Tokyo (JP)

Correspondence Address: SUGHRUE, MION, ZINN, MACPEAK & SEAS, PLLC, 2100 Pennsylvania Avenue, N.W., Washington, DC, 20037-3213, US

(21) Appl. No.: 09/726,123

(22) Filed: Nov. 30, 2000

(30) Foreign Application Priority Data
Nov. 30, 1999 (JP) 11-340276

(51) Int. Cl. H03B 19/00

(52) U.S. Cl. 327/119

(57) ABSTRACT

A purpose of the present invention is to provide an economical frequency multiplier with a simple structure, wherein a frequency of an input signal can be multiplied with high accuracy and the frequency multiplier is widely applicable to a device in which a high accurate high frequency is required. The frequency multiplier comprises at least a differential signal generating circuit 11 for receiving a sinusoidal wave input signal and generating two signals of which a frequency is as same as that of the input signal and a phase different is 180° and a multiplier circuit 12 for multiplying two signals from the differential signal generating circuit 11 and generating a signal of which a frequency component is double of an original frequency of the input signal so as to obtain an output signal of which a frequency is multiplied in response to the input signal.

### BACKGROUND OF THE INVENTION

1. Field of the Invention

The present invention relates to a frequency multiplier for receiving an output signal from a circuit such as an oscillating circuit and generating a signal by multiplying the frequency of the output signal.

As a conventional frequency multiplier, a PLL (Phase Locked Loop) circuit as shown in FIG. 11 has been known. The PLL circuit 51 comprises a phase comparator (PD), a loop filter (LF) 53, a voltage control oscillator (VCO) 54 and a frequency demultiplier 55. In the phase comparator 52, a phase of a clock signal from a clock signal generating circuit 56 and a phase of a clock signal by demultiplied 1/N in the frequency demultiplier 55 are compared. In accordance with the comparison result, an input voltage of the voltage control oscillator 54 is controlled through the loop filter 53 in order to coincident with the both phases so that the voltage control oscillator 54 can output a clock signal of which a frequency (N·fr) is N times multiplied by the frequency fr of a clock signal from the clock signal generating circuit 56.

As shown in FIG. 11, a clock signal generating circuit 56 comprises a crystal oscillating circuit 57 and a multiple-step inverter 58 (two step in FIG. 11) for demodulating a waveform of an output signal to a rectangular pulse. In the crystal oscillator circuit 57, a crystal oscillating circuit 62 and a feedback resistance 63 are connected in parallel between an input terminal and an output terminal of a CMOS inverter 61. The input terminal and the output terminal of the CMOS inverter 61 is connected to the ground through condensers 64 and 65, respectively so that a clock signal with the frequency fr can be output from the output terminal of the CMOS inverter 61 to the inverter 58.

As another conventional frequency multiplier, a frequency multiplier as shown in FIG. 12 has been known. The frequency multiplier 71 comprises an exclusive logical OR circuit 72 and a delay circuit 73. In a timing chart as shown in FIG. 2, a clock signal output from a clock signal generating circuit 74 is supplied to one input terminal of the exclusive logic OR circuit 72 and a phase of the clock signal is shifted 90° by the delay circuit 73 and supplied to the other input terminal of the exclusive logic OR circuit 72. Thereby, a frequency (2fr) multiplied two times by a frequency fr of a clock signal output from the clock signal generating circuit 74 can be obtained by the exclusive logic OR circuit 72. The clock signal is output through an inverter 75.

In FIG. 12, a structure of the clock signal generating circuit 74 is as similar as that of the clock signal generating circuit 56 as shown in FIG. 11. The same numerals are numbered to elements as shown in FIG. 12 corresponding to the same elements as shown in FIG. 11. Therefore, the description of the same components is omitted.

In a PLL circuit 51 as shown in FIG. 11, a clock signal with frequency fr output from the clock signal generating circuit 56 is designated as an input signal. By comparing a phase difference between the input clock signal and a clock signal demultiplied 1/N by an output clock signal of the voltage control oscillator 54, an output clock signal of which a frequency is N·fr can be obtained. However, depending on accuracy of the phase comparator 52, jitter and phase noise are apt to be occurred in the output clock signal.

Similarly, in the frequency multiplier 71 as shown in FIG. 12, a clock signal with frequency fr output from the clock signal generating circuit 74 is designated as an input signal. By exclusively logical summing the input clock signal and a clock signal of which a phase is shifted by 90° from an original phase of the input clock signal, an output clock signal with frequency 2fr can be obtained. Therefore, depending on its accuracy for producing a clock signal of which a phase is shifted by 90°, jitter and phase noise are apt to be occurred in the output clock signal.

In the above described conventional frequency multiplier, a frequency of an input signal can not be multiplied with high accuracy due to an occurrence of jitter and phase noise. In order to reduce a baneful influence caused by jitter and the phase noise, an extra complete circuit is necessary with some difficulties. Therefore, its application is restricted and only applicable to a device in which a high frequency signal is required, such as a measuring device, a mobile communication tool and so on with high accuracy.

To resolve the above drawbacks, a purpose of the present invention is to provide a frequency multiplier with a low price and a simple circuit structure wherein a frequency of an input signal can be multiplied with high accuracy and the frequency multiplier can be easily and widely utilized to a general-purpose device in which a high frequency signal is required with high accuracy.

### SUMMARY OF THE INVENTION

To accomplish the above purpose, a frequency multiplier according to the present invention comprises at least a differential signal generating circuit for producing two different signals of which a phase difference is 180° each other although the both frequency are equal to that of the input signal and a multiplying circuit for multiplying two signals output from the differential signal generating circuit and generating a signal with a frequency component which is double of the frequency of the input signal, wherein the frequency multiplier is characterized of obtaining an output signal of which a frequency is multiplied in response to the input signal.

Regarding the first aspect of the present invention, in the case of indicating a sinusoidal wave input signal [symbol] , two signals, that is, sin ωt and sin (ωt+ can be output from the differential signal generating circuit. In the multiplying circuit for multiplying these two signals, an output signal of −(1−cos 2ωt)/2 includes a frequency component that is double of that of the input signal frequency. Accordingly, by providing the above multiplying circuit and the above differential signal circuit and so on, in the case of multiplying two sinusoidal wave signals of which a frequency component is optional times of an original frequency of an input signal, a sinusoidal wave output signal of which a frequency is optional times (more than two times) of that of the input signal can be obtained. By modulating the sinusoidal wave of the output signal, a clock signal can be obtained easily. Thus, a frequency can be multiplied with high accuracy without occurring jitter and phase noise by providing an economic circuit with a simple structure.

Regarding the second aspect of the present invention, a frequency multiplier according to the present invention comprises at least an in-phase signal generating circuit for receiving a sinusoidal wave input signal and outputting two signals of which each frequency is the same of the input signal and the both phases are equal, and a multiplying circuit for multiplying two signals from the in-phase signal generating circuit and generating a signal of which a frequency component is double of an original frequency of the input signal, wherein the frequency multiplier is characterized of generating an output signal of which a frequency is multiplied by that of the input signal.

In the above described embodiment, in the case of indicating a sinusoidal wave input signal as sin ωt, two signals of sin ωt (or −sin ωt) can be obtained from the in-phase signal generating circuit. In the multiplying circuit for multiplying these two signals, an output signal of (1−cos 2ωt)/2 including a frequency component that is double of the original frequency of the input signals can be obtained. Accordingly, as similar as the present invention as recited in claim 1, by providing the above multiplying circuit and the above in-phase signal generating circuit and so on, two sinusoidal wave signals of which a frequency is optional times of that of the input signal are multiplied so as to generate a sinusoidal wave output signal of which a frequency is optional times (more than two times) of that of the input signal. By modulating the sinusoidal wave output signal, a clock signal can be obtained easily. Thereby, a frequency of the input signal can be multiplied with high accuracy without occurring jitter and phase noise by providing an economic circuit with a simple structure.

### BRIEF DESCRIPTION OF THE DRAWINGS

FIG. 1 is a block diagram for showing a structure of a clock signal generator with the first embodiment of a frequency multiplier according to the present invention.

FIG. 2 shows an example of a circuit of a differential signal generating circuit employed in the embodiment as shown in FIG. 1.

FIG. 3 shows a block diagram of a modified embodiment of a clock signal generator as shown in FIG. 1.

FIG. 4 is a block diagram for showing a clock signal generator with the second embodiment of a frequency multiplier according to the present invention.

FIG. 5 is an example of a circuit of an in-phase signal generating circuit employed in the embodiment as shown in FIG. 4.

FIG. 6 is a block diagram of a modified embodiment of the clock signal generator as shown in FIG. 4.

FIG. 7 shows a block diagram of a clock signal generator with the third embodiment of a frequency multiplier according to the present invention.

FIG. 8 is a block diagram of a modificated embodiment of a frequency multiplier according to the present invention.

FIG. 9 is a block diagram of another modificated embodiment of a frequency multiplier according to the present invention.

FIG. 10 is a block diagram of another modificated embodiment.

FIG. 11 shows a block diagram of a conventional frequency multiplier.

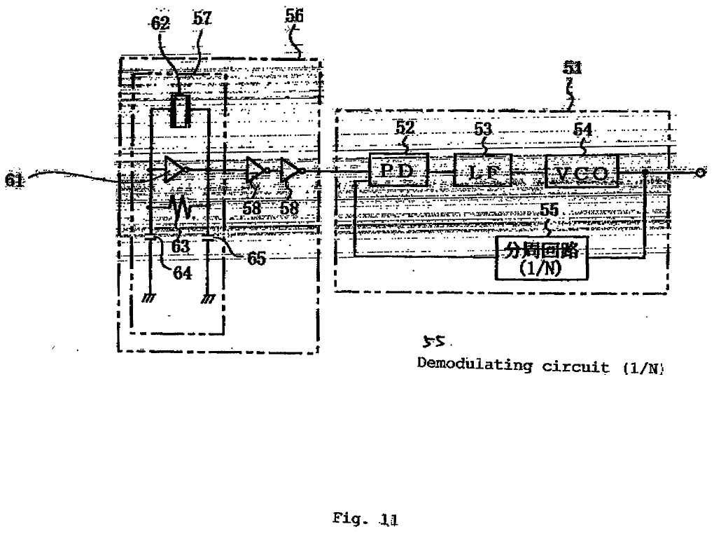

FIG. 12 shows a block diagram of another conventional frequency multiplier.

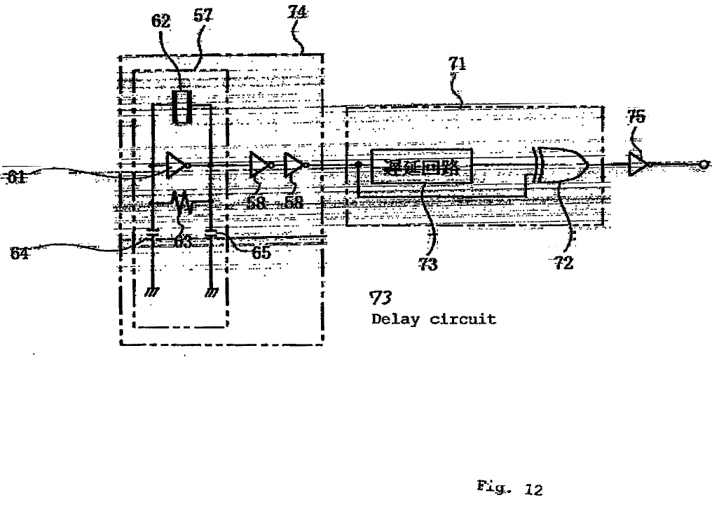

FIG. 13 is a timing chart for explaining an operation as shown in FIG. 12. An upper pulse is an output of a clock signal generating circuit. An intermediate pulse is an output of a delay circuit. A lower pulse is an output of an exclusive logic OR circuit.

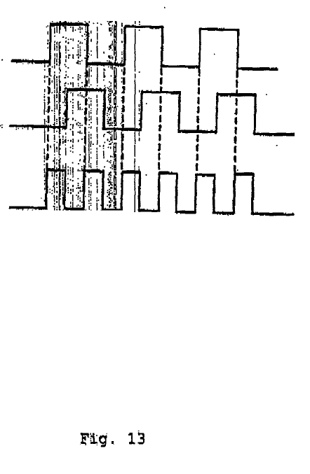

### PREFERRED EMBODIMENTS OF THE INVENTION

An embodiment of a frequency multiplier according to the present invention will be explained with reference to the accompanying drawings.

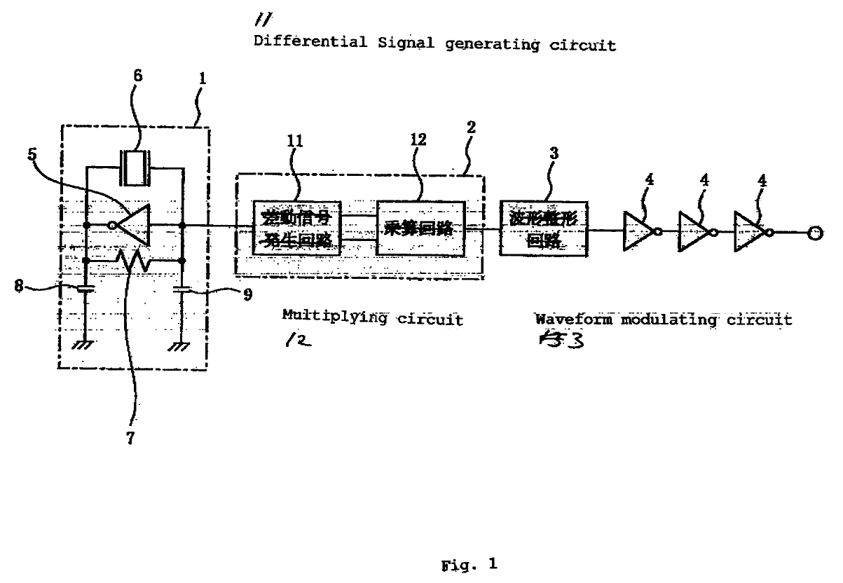

FIG. 1 is a first embodiment of a block diagram of a clock signal generator with a frequency multiplier according to the present invention. The clock signal generator comprises a crystal oscillating circuit 1, a frequency multiplier 2 for two times multiplying an original frequency of a sinusoidal wave output signal output from the crystal oscillating generator 1, a waveform modulating circuit 3 for modulating the output signal output from the frequency multiplier 2 to a clock signal and a multi-step (three steps in FIG. 1) inverter 4 connected to an output terminal of the wave modulating circuit 3.

As similar as a conventional art described above, in the crystal oscillator 1, a crystal oscillator 6 and a feedback resistance 7 are connected between an input terminal and an output terminal of a CMOS inverter 5 in parallel. The input terminal and the output terminal of the CMOS inverter 5 is connected to the ground via condensers 8 and 9, respectively so as to supply a sinusoidal wave signal generated at the input terminal of the CMOS inverter 5 to a frequency multiplier 2.

The frequency multiplier 2 comprises a differential signal generating circuit 11 for receiving a sinusoidal wave output signal output from the crystal oscillating circuit 1 and generating two different signals of which each frequency is the same frequency and a phase difference is 180° and a multiplying circuit 12 for multiplying two signals output from the differential signal generating circuit 11. The frequency multiplier 2 supplies an output signal output from the multiplying circuit 12 to a waveform modulating circuit 3.

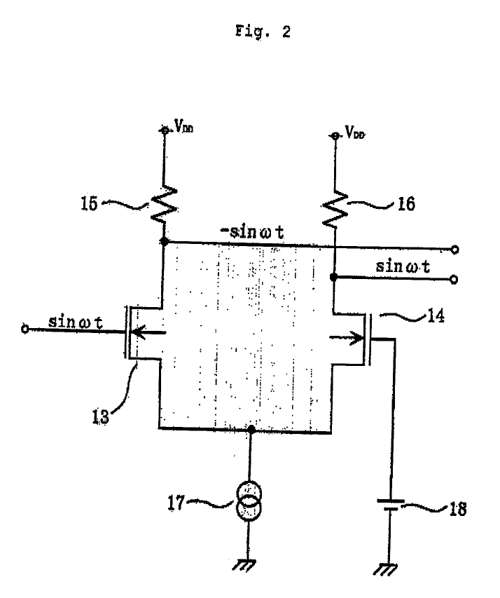

As shown in FIG. 2, the differential signal generating circuit 11 comprises a pair of differential set including two field-effect transistors (FET) 13 and 14 having the same characteristic, resistances 15 and 16 respectively connected to a portion between each drain of the FETs 13 and 14 and a battery voltage V_{DD}, and a constant-current source 17 connected to a common source of the FETs 13 and 14. A sinusoidal wave signal output from the crystal oscillating circuit 1 is supplied to a gate of the FET 13 and a reference battery 18 is connected to a gate of the other FET 14 so that a sinusoidal wave signal of which a phase is shifted 180° from an original phase of an input sinusoidal wave signal output from the drain of the FET 13 and a sinusoidal wave signal of which a phase is as same as that of the input sinusoidal wave signal output from the drain of the FET 14 can be obtained. Thus, two signals of which each frequency is as same as an original frequency of the input sinusoidal signal and the phases difference is 180°.

Under a structure as shown in FIG. 1, when a sinusoidal wave signal of sin ωt is input from the crystal oscillating circuit 1 to the differential signal generating circuit 11 in the frequency multiplier 2, two signals of sin ωt and −sin ωt are output from the differential signal generating circuit 11. These signals are multiplied in the multiplying circuit 12 so as to generate an output signal of −(1−cons 2ωt)/2 of which a frequency component is double of an original frequency of the input signal output from the crystal oscillating 1. Accordingly, if the output signal from the multiplying circuit 12 is picked up through the waveform modulating circuit 3 and a multi-step inverter 4, it can be obtained a clock signal of which a frequency is double of that of the input signal output from the crystal oscillating circuit 1.

In a clock signal generator as shown in FIG. 1, the frequency multiplier 2 does not treat with a rectangular wave clock signal and generates a sinusoidal wave output signal of which a frequency is double of that of the input signal by treating the sinusoidal wave signal. A waveform of the output signal generated from the frequency multiplier 2 is modulated so as to obtain a clock signal. Thereby, a clock signal of which a frequency is double of that of the sinusoidal signal with high accuracy without occurring jitter and phase noise.

In the crystal oscillator 1, a reference sinusoidal wave signal of which a frequency is multiplied by that of an input signal is obtained so that a high frequency clock signal can be obtained by fundamentally oscillating the crystal oscillator 6. Accordingly, the crystal oscillator 6 can be down sized easily and driven at a low voltage. Thus, it can be accomplished to provide a compact high frequency clock signal generator driven at a low voltage. In addition, a range of the oscillated frequency can be broadly varied by fundamentally oscillating the crystal oscillator 6 so that the crystal oscillating circuit 1 can be applied to a high frequency voltage controlled crystal oscillator (VCXO).

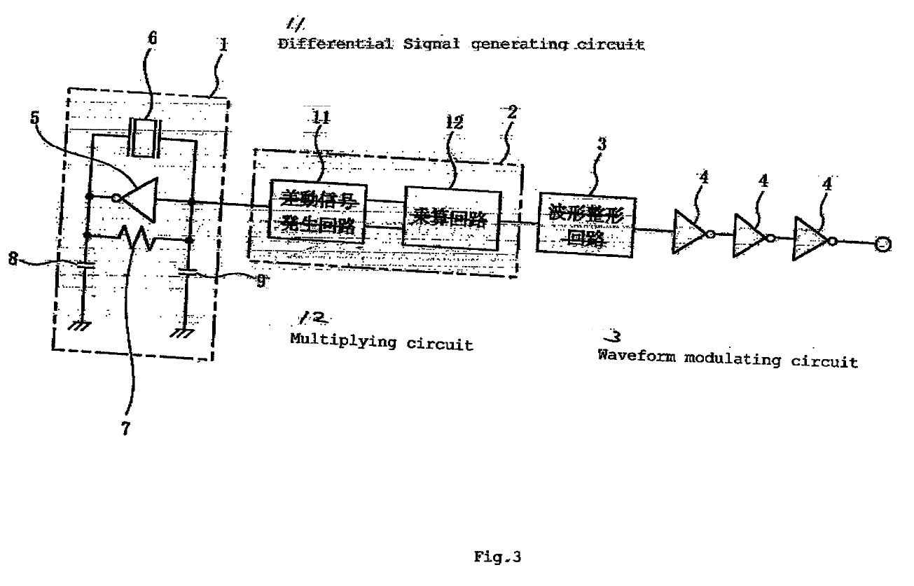

In the clock signal generator as shown in FIG. 1, a sinusoidal wave signal is picked up from an input terminal of the CMOS inverter 5 in the crystal oscillating circuit 1. In the case of oscillating the crystal oscillating circuit fundamentally or with over tone, a signal generated at the output terminal of the CMOS inverter 5 is a sinusoidal wave. In such a case, as shown in FIG. 3, a sinusoidal wave oscillating output signal may be supplied from the output terminal of the CMOS inverter 5 to the differential signal generating circuit 11 in the frequency multiplier 2.

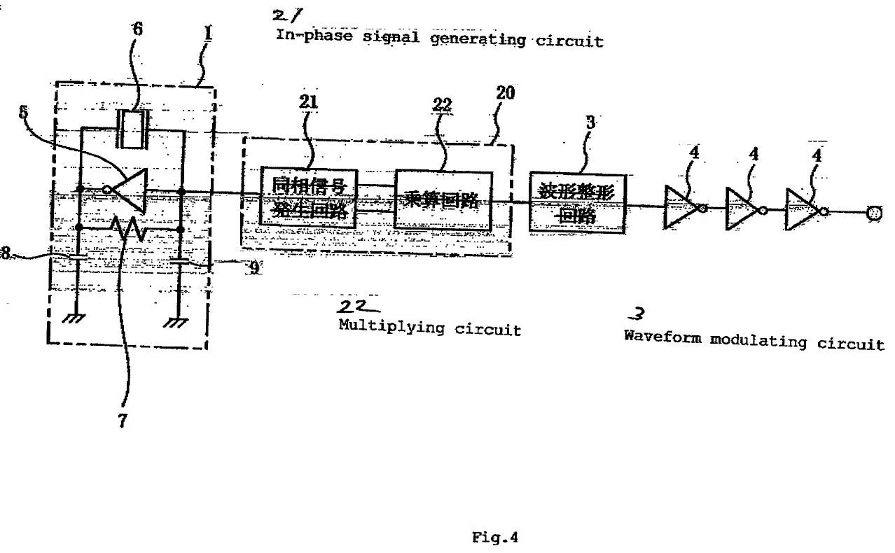

FIG. 4 is a block diagram for showing a clock signal generator with a second embodiment of a frequency multiplier according to the present invention. In the clock signal generator, a frequency multiplier 20 comprises an in-phase signal generating circuit 21 for generating two signals of which each frequency and phase are equal each other and a multiplier circuit 22 for multiplying two signals output from the in-phase signal generating circuit 21. The other elements are as same as those of the clock signal generator as shown in FIG. 1. The same numerals are numbered to elements as shown in FIG. 4 corresponding to the same elements as shown in FIG. 1. Therefore, an explanation of these elements is omitted.

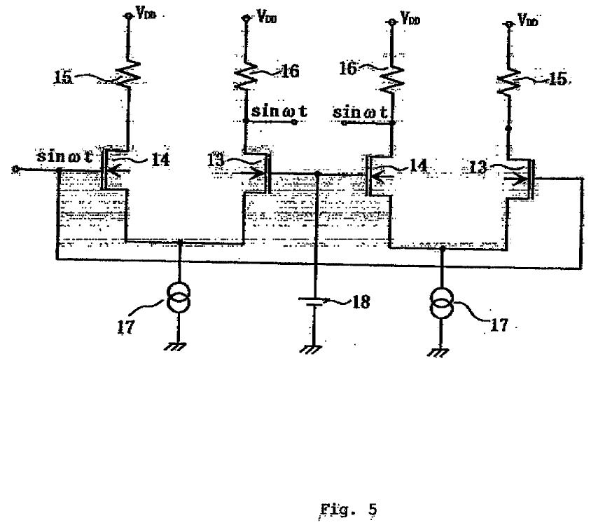

In a circuit as shown in FIG. 5, an in-phase signal generating circuit 21 comprises two pairs of differential sets including two FETs 13 and 14 and two resistances 15 and 16, and a constant-current source 17 as shown in FIG. 2. A sinusoidal wave signal output from the crystal oscillating circuit 1 is supplied to a gate of each FETs 13 and 13 and a reference battery source 18 is connected to a gate of each FET 14 and 14 so as to generate two signals of which each frequency and each phase is as same as those of a sinusoidal input signal output from the drain of the FETs 14 and 14, respectively.

Under the structure as shown in FIG. 4, when a sinusoidal wave signal of sin ωt is supplied from the crystal oscillating circuit 1 to the in-phase signal generating circuit 21 in the frequency multiplier 20, two in-phase signals of sin ωt are output from the in-phase signal generating circuit 21. These in-phase signals are multiplied by a multiplying circuit 22 so as to generate an output signal of (1−con 2ωt)/2, that is, the output signal of which a frequency component is double of that of input signal output from the crystal oscillating circuit 1. Accordingly, if an output signal of the multiplying circuit is picked up through the waveform modulating circuit 3 and a multi-step inverter 4, it can be obtained a clock signal of which a frequency is double of that of the input signal output from the crystal oscillating circuit 1.

In a clock signal generating circuit as shown in FIG. 4, the frequency multiplier 20 does not treat a rectangular wave clock signal, obtains a sinusoidal wave output signal of which a frequency is double of that of a sinusoidal wave signal and modulates a waveform of the output signal output from the frequency multiplier 20 so as to obtain a clock signal. The clock signal generator as shown in FIG. 4 can obtain an effect as similar as the clock signal generator as shown in FIG. 1, since a reference sinusoidal wave signal of which a frequency is a reference frequency to be multiplied can be obtained by the crystal oscillating circuit 1.

In the embodiment of a frequency multiplier 20 according to the present invention, two signals of which each frequency is as same as that of the input sinusoidal wave signal output from the in-phase generating circuit 21 and the respective phase is equal each other. In the in-phase generating circuit 21 as shown in FIG. 5, it may be picked up two signals of which each frequency is as same as that of the input sinusoidal wave signal output from a drain of the FETs 13 and 13 and the phases are opposite each other.

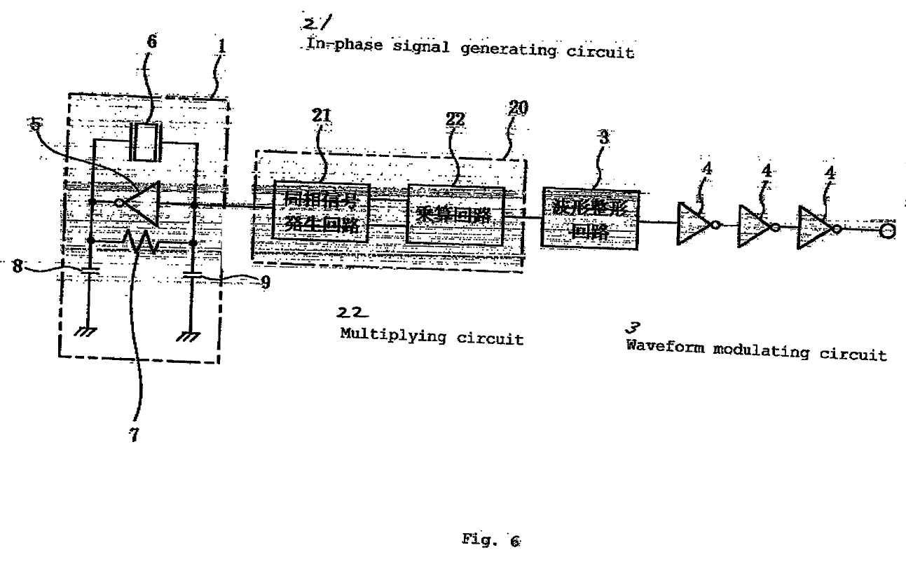

In the clock signal generating circuit as shown in FIG. 4, in the case of oscillating a high frequency fundamentally or with over tone by the crystal oscillating circuit 1, a signal generated at an output terminal of the CMOS inverter 5 is a sinusoidal wave. In such a case, as shown in FIG. 6, the sinusoidal wave oscillating output signal may be supplied from an output terminal of the CMOS inverter 5 to the in-phase signal generating circuit 21 in the frequency multiplier 20.

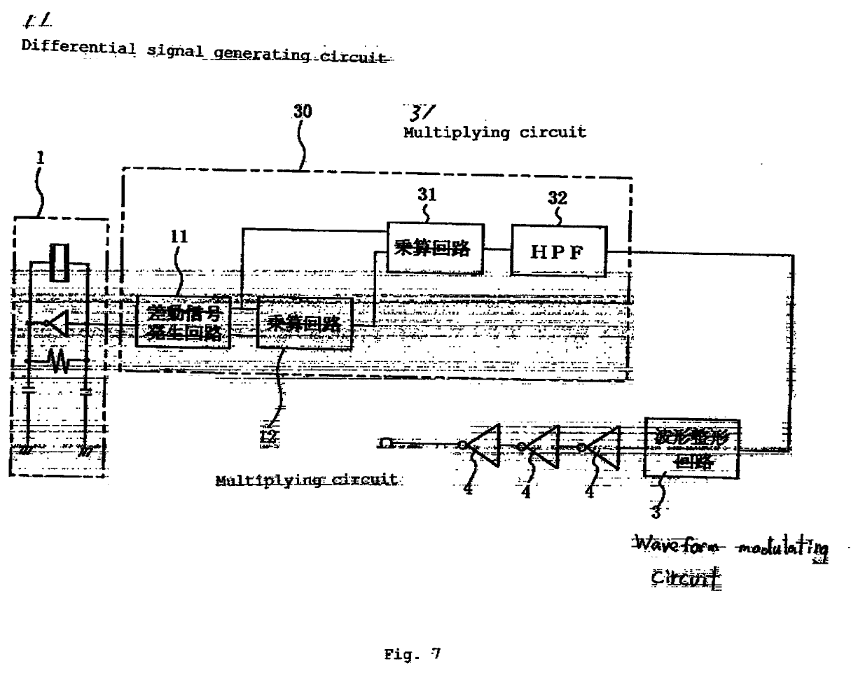

FIG. 7 shows a block diagram for showing a clock signal generator with a third embodiment of a frequency multiplier according to the present invention. The clock signal generator comprises a frequency multiplier 30 including a differential signal generating circuit 11 and a multiplier circuit 12 as shown in FIG. 1, further comprises a multiplier circuit 31 and a high path filter (HPF) 32. In the multiplier circuit, one output signal of the differential signal generating circuit 11 and an output signal of the front step in the multiplier circuit 12 are multiplied and the output signal output from the multiplier circuit 31 is supplied to a waveform modulating circuit 3 through a HPF 32. Such a structure is as same as the structure of the clock signal generator as shown in FIG. 1. The same numerals are numbered to elements as shown in FIG. 4 corresponding to the same elements as shown in FIG. 1. Therefore, the description of the same elements is omitted.

In the structure as shown in FIG. 7, when a sinusoidal wave signal of sin ωt is input from a crystal oscillating circuit 1 to a differential signal generating circuit 11 in a frequency multiplying circuit 30, as similar as an embodiment as shown in FIG. 1, an output signal of −(1-cos 2ωt)/2 can be generated from the multiplying circuit 12. If theoutput signal output from the multiplier circuit 12 and one of output signals output from the differential signal generating circuit 11 (i.e. sin ωt) are multiplied by the multiplying circuit 31, an output signal of (sin 3 ωt+sin ωt)/2 can be obtained. Accordingly, if the output signal of the multiplying circuit 31 is supplied to the HPF 32 in order to pass the frequency component of sin 3ωt only and the frequency component is picked up through a waveform modulating circuit 3 and a multi-step inverter 4, a clock signal of which a frequency is triple of that of the input signal from a crystal oscillating circuit 1 with high accuracy without occurring jitter and phase noise.

In the structure as shown in FIG. 7, the differential signal generating circuit 11 in the frequency multiplier 30 can be instead of the in-phase signal generating circuit 21 as shown in FIG. 4.

A variation of the present invention is not restricted by the embodiments as described above. The present invention can be broadly modified within a range of an essence of the present invention. For example, although a reference sinusoidal wave signal of which a frequency is a reference frequency to be multiplied can be obtained by a crystal oscillating circuit 1 with the CMOS inverter 5, a ceramic oscillating circuit, a LC oscillating circuit and the other oscillating circuits can be utilized if a sinusoidal wave signal is supplied to a frequency multiplier.

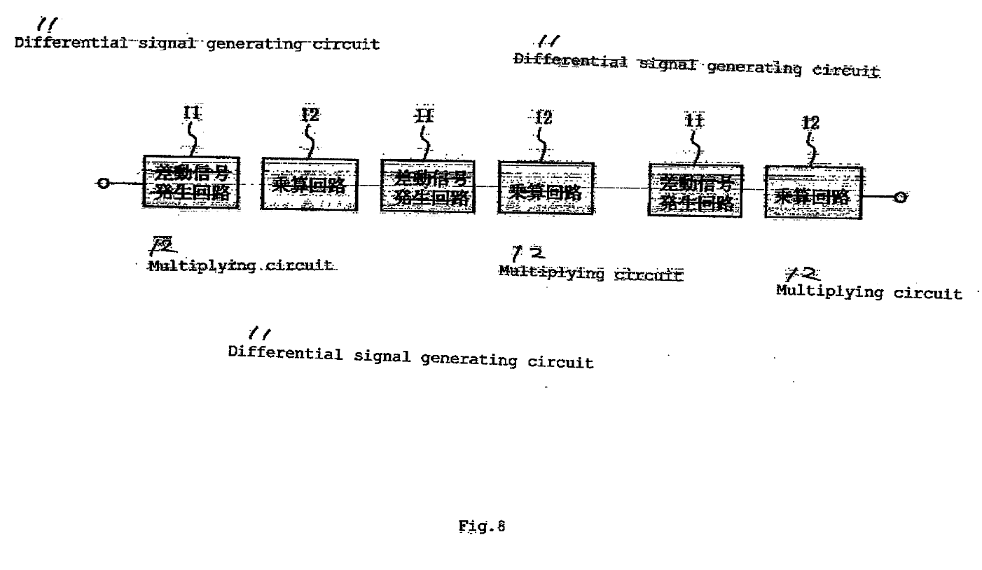

A frequency multiplier comprises a pair of the differential signal generating circuit 11 and the multiplier circuit 12 as shown in FIG. 2 as one step in a multiplying process and further comprises a plurality of pairs, n pairs, of steps (n is an integer equal or more than 2) connected in series as shown in FIG. 8 so as to obtain an output signal of which a frequency is 2ⁿ multiplied by that of the input signal. Similarly, it may comprise a pair of the in-phase signal generating circuit 21 and the multiplier circuit 22 as shown in FIG. 4 as one step in a multiplying process, and further comprises a plurality of pairs, n pairs (n is an integer equal or more than two) connected in series so as to obtain an output signal of which a frequency is 2ⁿ multiplied by that of input signal. As shown in FIG. 8, a pair of the differential signal generating circuit 11 and the multiplying circuit 12 and a pair of the in-phase signal generating circuit 21 and the multiplying circuit 22 may be combined.

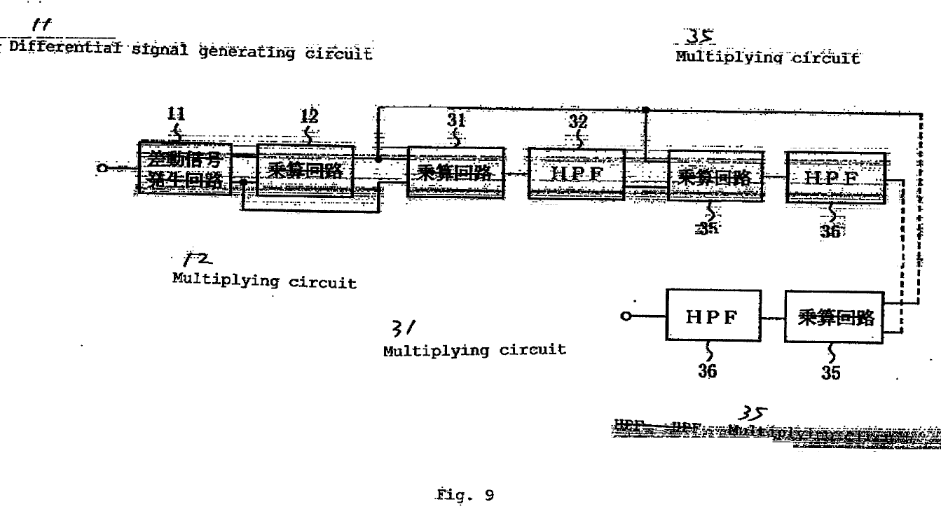

In addition, the frequency multiplier comprises the differential signal generating circuit 11, the multiplier 12, the multiplier 31 and a HPF 32 as shown in FIG. 7. A pair of the multiplier circuit 35 and the HPF 36 as shown in FIG. 9 are designated as one step in a multiplying process and m pairs of the multiplier circuits 35 and the HPFs 36 (m is a positive integer) are connected in series. A high frequency component which is odd number times of that of an input signal output from a former set of the multiplying circuit in each step through the HPF and a frequency component which is double of that of an input signal output from the first multiplying circuit 12 are multiplied so that an output signal of which a frequency is (2m+39 times of that of the input signal. In such a case, of course, the in-phase signal generating circuit 21 as shown in FIG. 4 may be utilized instead of the differential signal generating circuit 11.

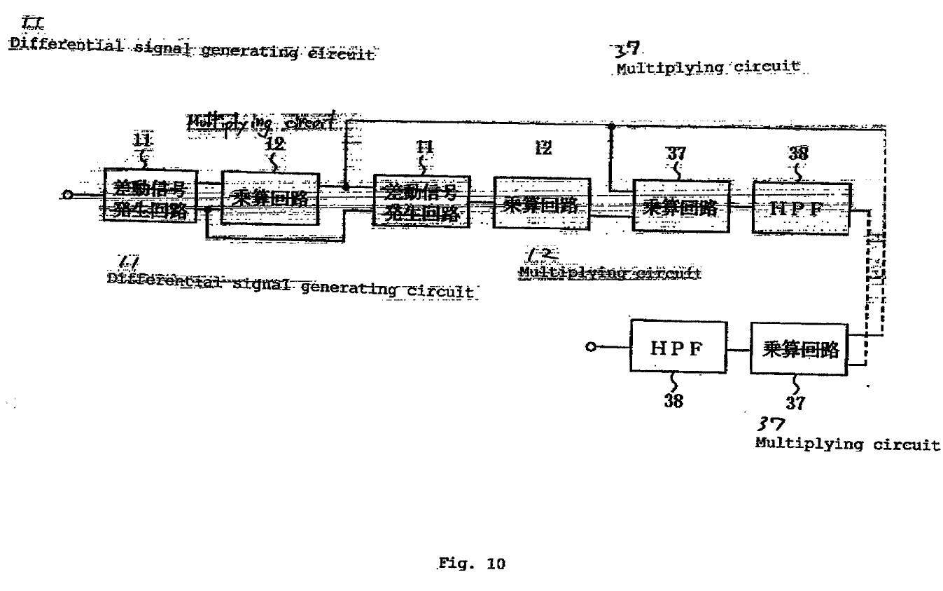

As shown in FIG. 10, in a frequency multiplier, two pairs of the differential signal generating circuits 11 and the multiplying circuits 12 are connected in series and then m pairs (m is a positive integer) of the multiplying circuits 37 and the HPF 38 is successively connected in series. A multiplying circuit 37 in the first step multiplies a frequency component which is double of an original frequency obtained from the multiplying circuit 12 in the set pair and a frequency component which is four times of an original frequency obtained from a multiplying circuit in the second pair. The multiplying circuit in each following step multiplies a frequency component which is double of an original frequency obtained from the multiplying circuit 12 in the first step and a frequency component which is even number times of the original frequency obtained from the former multiplying circuit 37 through the HPF 38. Thereby, it can be obtained an output signal which is (2m+4) times of an original frequency of the input signal. Of course, in such a case, the in-phase signal generating circuit 21 as shown in FIG. 4 may be used instead of one or two differential signal generating circuit 11.

In the above embodiment, although a frequency multiplier is applied to a clock signal generating circuit, it may omit the waveform modulating circuit 3 and the inverter 4 and can obtain a sinusoidal wave output signal multiplied by a sinusoidal wave input signal.

In a frequency multiplier according to the present invention, a rectangular wave clock signal is not treated. The frequency multiplier comprises at least a differential signal generating circuit for outputting two signals of which a frequency is equal to an original frequency of a sinusoidal wave input signal and a phase difference is 180°, or an in-phase generating circuit for generating two signals of which a frequency is equal to that of the input signal and a respective phase is equal each other and a multiplier circuit for multiplying two signals generated from the differential signal generating circuit or the in-phase generating circuit. Thus, the frequency multiplier according to the present invention can be economically manufactured with a simple structure without occurring jitter and phase noise. The frequency multiplier according to the present invention can be easily applied to a device in which a frequency signal is required with high accuracy for a general purpose.

What is claimed is:

1. A frequency multiplier comprising:
a differential signal generating circuit for receiving a sinusoidal wave input signal with an original frequency and generating two signals of which a frequency is as same as said original frequency of the input signal and a phase difference is 180°; and
a multiplying circuit for multiplying two signals output from said differential signal generating circuit and generating a signal including a frequency component which is double of said original frequency of said input signal,
wherein said frequency multiplier is characterized of generating an output signal multiplied by said original frequency of said input signal.

2. A frequency multiplier comprising:
an in-phase signal generating circuit for receiving a sinusoidal wave input signal with an original frequency and generating two signals of which a frequency is equal to said original frequency of said input signal and each phase are the same each other; and
a multiplying circuit for multiplying two signals output from said in-phase signal generating circuit and generating a signal including a frequency component which is double of said original frequency of said input signal,
wherein said frequency multiplier is characterized of generating an output signal multiplied by said original frequency of said input signal.
